(19) United States
(12) Patent Application Publication
(10) Pub. No.: US 2005/0095867 A1
(43) Pub. Date: May 5, 2005

(54) Method of manufacturing semiconductor device

(76) Inventor: Hiroyuki Shimada, Kofu-city (JP)

Correspondence Address: EDWARDS & ANGELL, LLP, P.O. BOX 55874, BOSTON, MA, 02205, US

(21) Appl. No.: 10/918,114

(22) Filed: Aug. 12, 2004

(30) Foreign Application Priority Data
Aug. 12, 2003 (JP) 2003-292041
Sep. 17, 2003 (JP) 2003-324451

(51) Int. Cl. H01L 21/302; H01L 21/322; H01L 21/461

(52) U.S. Cl. 438/720

(57) ABSTRACT

A method of manufacturing a semiconductor device, comprising: forming an insulating layer on a semiconductor layer; forming a conductive layer including at least either a tantalum layer or a tantalum nitride layer on the insulating layer; and etching the conductive layer using a gas containing SiCl₄, NF₃, and an oxygen-containing material.

Japanese Patent Application No. 2003-292041, filed on Aug. 12, 2003 and Japanese Patent Application No. 2003-324451, filed on Sep. 17, 2003, are hereby incorporated by reference in its entirety.

### TECHNICAL FIELD

The present invention relates to a method of manufacturing a semiconductor device that has specific characteristics in a method of etching a conductive layer including at least any of tantalum and tantalum nitride, and specifically in a method of etching a gate electrode.

### DESRIPTION OF THE RELATED ART

As for a Metal Insulator Semiconductor Field Effect Transistor (MISFET, sometimes called an “insulated gate field-effect transistor IGFET”) that is used for today's semiconductor integrated circuits, a polycrystalline silicon layer, doped with a high impurity concentration, is often used as a gate electrode thereof for the reduction of resistance. However, it is known that despite the fact that the polycrystalline silicon layer, which forms a gate electrode, is doped with a high impurity concentration, a portion of a gate insulating layer is depleted at the time of channel inversion. The occurrence of such depletion is equivalent to a capacity being inserted in series with the gate electrode, thus reducing the effective electric field that is applied to a channel. As a result, current drive capability of the MISFET decreases. In order to solve this problem, using metal as the gate electrode material, which is of a low resistivity and does not cause depletion of the gate, is under study.

A technology using tantalum as a metal gate electrode is disclosed in the Japanese laid-open patent publication No. H11-168212. Forming a gate electrode by carrying out an anisotropic etching of a tantalum layer by SiCl₄ plasma is described in paragraph 0015 of the reference. However, the inventor of this patent publication confirmed that, in case of carrying out the anisotropic etching of the tantalum layer only by SiCl₄, the tantalum remains on a substrate without being etched uniformly, and thus taking a longer time to etch this completely.

Moreover, in the Japanese laid-open patent publication No. 2002-83805, etching a gate electrode, which is made of a metal with a high melting-point or an alloy including such a metal, by using a chlorine gas and a fluorine gas is disclosed. In this method, sidewalls of the gate electrode are tapered by the above-mentioned etching. As for the cross sectional shape of the tapered gate electrode, a width of the lower part becomes larger than that of the upper part. Moreover, in this method, impurities are doped in self-alignment using the tapered gate electrode as a mask (paragraph 0028 of this reference.). Furthermore, in this technology, a combination of Cl₂ and CF₄ (table 1 in paragraph 0065, etc.) or a combination of Cl₂ and SF₆ (table 2 in paragraph 0103, etc.) is used as the gas for the dry etching. However, an object of this method is to process the gate electrode so as to be a tapered shape, therefore the sidewalls of the gate electrode cannot be processed perpendicularly or with an angle close to perpendicular.

Furthermore, in the Japanese laid-open patent publication No. H5-102090, etching a metal layer such as aluminum by using an etchant material containing a coating composition and a chemical etchant composition is disclosed. In this method, sidewalls of the metal layer are processed by the above-mentioned etching so as to be perpendicular or a tapered shape. As for the cross sectional shape of the tapered gate electrode, a width of the lower part becomes larger than that of the upper part (FIG. 3, FIG. 4, etc.). However, in this method, the metal layer is processed so as to be a tapered shape, and there is no specific description at what conditions the sidewalls of the metal layer become perpendicular. Furthermore, there is no description for processing perpendicularly the sidewalls of the conductive layer that includes at least either tantalum and tantalum nitride.

### SUMMARY

A method of manufacturing a semiconductor device in accordance with at least one of the embodiments of the present invention comprises: forming an insulating layer above a semiconductor layer; forming a conductive layer including at least one type selected from the IVa, Va, and VIa group metals and nitrides of these metals above the insulating layer; and etching the conductive layer using a gas containing SiCl₄, NF₃, and an oxygen-containing material.

In at least one of the embodiments of the present invention, the IVa, Va, and Via group metals indicate metals with a high melting-point such as tantalum, molybdenum, and tungsten. The preferred embodiment is applicable to tantalum, which is especially difficult to etch.

In at least one of the embodiments of the present invention, an “oxygen-containing material” means oxygen or an oxygen compound such as water, and preferably oxygen.

In at least one of the embodiments of the present invention, when etching the conductive layer including at least either the tantalum layer and the tantalum nitride layer, the conductive layer can be etched promptly and in a favorable shape by using the gas containing SiCl₄, NF₃, and an oxygen-containing material, while securing a high selection ratio against the insulating layer. A “favorable shape” means that sidewalls of the patterned conductive layer are perpendicular or almost perpendicular without having a tapered shape. “Almost perpendicular” means that the angle between the sidewalls of the etched conductive layer and the surface of the insulating layer, provided underneath the conductive layer, is 85° to 90°, preferably 89° to 90°.

In at least one of the embodiments of the present invention, in addition to the capability of etching the conductive layer including at least either the tantalum and the tantalum nitride promptly and in a favorable shape, the time duration required for etching can be reduced, while securing a high selection ratio against the insulating layer. This is because the etching of the conductive layer is divided into two steps, and the fluorocarbon, whose etching rate to the conductive layer is higher compared with other gases, is used in a first step.

In at least one of the embodiments of the present invention, the first tantalum nitride layer is formed in contact with the gate insulating layer. The work function of the tantalum nitride is about 4.5 eV, which is extremely close to the intrinsic mid-gap energy 4.61 eV of silicon. As a result, an increase of the absolute value of flat band voltage of an MIS capacitor, formed of metal/insulating layer/silicon, can be reduced, and a difference of the absolute value of an n-channel insulated-gate field-effect transistor and a p-channel insulated-gate field-effect transistor can be made significantly small. Therefore, as for a complementary-type semiconductor device mounting a mix of the n-channel insulated-gate field-effect transistor and the p-channel insulated-gate field-effect transistor having a structure of a fully-depleted type SOI, a threshold balance of the both can be correctly and easily controlled.

### BRIEF DESCRIPTION OF THE DRAWINGS

FIG. 1 is a cross sectional view showing a semiconductor device obtained by a manufacturing method according to an embodiment.

FIG. 2 is a cross sectional view showing a method of manufacturing a semiconductor device according to the embodiment.

FIG. 3 is a cross sectional view showing a method of manufacturing a semiconductor device according to the embodiment.

FIG. 4 is a cross sectional view showing a method of manufacturing a semiconductor device according to the embodiment.

FIG. 5 is a graph showing a relationship of the composition of an etching gas and a selection ratio.

FIG. 6 is a graph showing a relationship of the composition of an etching gas and a selection ratio.

FIG. 7 is a view showing a SEM photograph of an etched layer.

FIG. 8A and FIG. 8B are views showing SEM photographs of etched layers.

FIG. 9 is a graph showing a relationship of an over-etching time and a thickness of a deposition layer.

FIG. 10 is a graph showing a relationship of an oxygen concentration and a thickness of a deposition layer.

FIG. 11 is a chart showing a result of an X-ray electronic spectral analysis of a deposition layer.

FIG. 12A and FIG. 12B are graphs showing Id-Vg characteristics of transistors.

FIG. 13 is a graph showing a relationship of an off-current of a transistor and cumulative number.

FIG. 14 is a view showing an etched conductive layer according to a comparison experiment.

### DETAILED DESCRIPTION

Hereinafter, embodiments of the present invention will be described with reference to drawings.

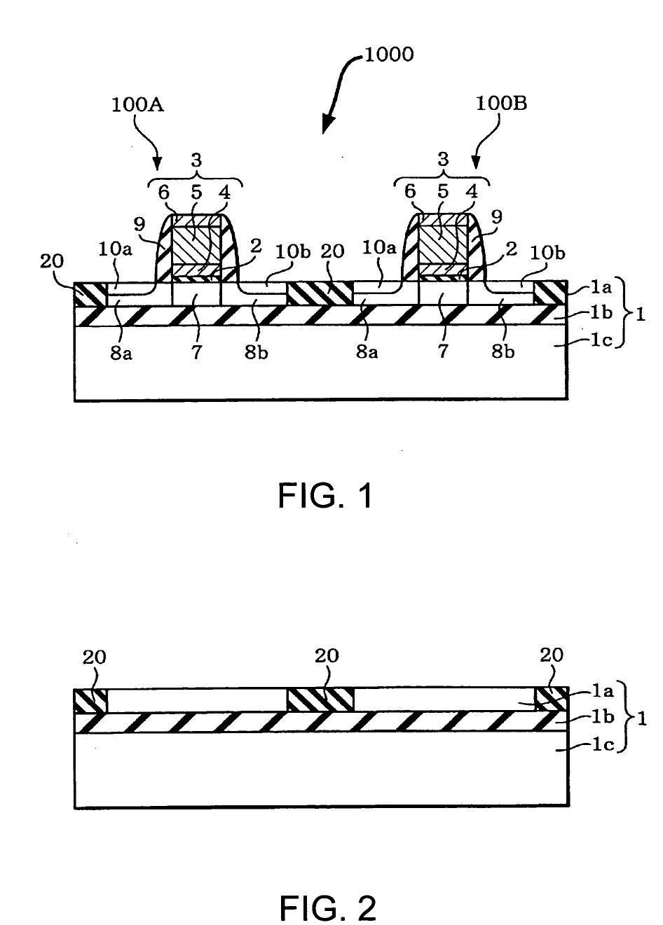

FIG. 1 is a cross sectional view schematically showing a semiconductor device 1000 obtained by a manufacturing method according to an embodiment of the present invention. The semiconductor device 1000 is a complementary type semiconductor device, which includes an n-channel insulated gate field-effect transistor (NMISFET) 100A and a p-channel insulated gate field-effect transistor (PMISFET) 100B. The NMISFET 100A and the PMISFET 100B are formed on an SOI (Silicon On Insulator) substrate 1. The SOI substrate 1 is formed by depositing an insulating layer (silicon oxide layer) 1b and a semiconductor layer 1a on a supporting substrate 1c. As for the embodiment, the semiconductor layer 1a is a silicon layer. In addition, the semiconductor layer may be a bulk semiconductor substrate.

The NMISFET 100A and the PMISFET 100B are isolated by an isolation region 20, formed in the semiconductor layer 1a of the SOI substrate 1.

Each of the MISFET 100A and 100B has a structure in which a stacked type gate electrode 3 is formed above the semiconductor layer 1a via a gate insulating layer 2. The stacked type gate electrode 3 is formed by sequentially depositing a first tantalum nitride layer 4, a tantalum layer 5 of a body-centered cubic lattice phase, and a second tantalum nitride layer 6 as a cap layer. As for the embodiment, the tantalum of a body centered cubic lattice phase is sometimes described as a-tantalum or a bcc-tantalum (body centered cubic Ta). Moreover, a channel region 7 is formed directly underneath the gate insulating layer 2, and impurity layers 8a and 8b, which form a source region or a drain region, are formed at both sides of the channel region 7.

Then, as for the NMISFET 100A, the impurity layers 8a and 8b are formed as n-type, and as for the PMISFET 100B, the impurity layers 8a and 8b are formed as p-type. Silicide layers 10a and 10b are formed in the upper portions of the impurity layers 8a and 8b, respectively.

Next, a method of manufacturing the semiconductor device 1000 according to the embodiment will be described with reference to FIGS. 2 through 4.

(a) The SOI substrate 1, where the insulating layer (silicon oxide layer) 1b and the semiconductor layer 1a, formed of p-type silicon having a low concentration, are deposited on the supporting substrate 1c, is prepared. The semiconductor layer 1a has a thickness of 50 nm, a resistivity of 14 to 26 ohm-cm, and a plane direction of (100), for example. At first, as shown in FIG. 2, the isolation region 20 is formed in the p-type-semiconductor layer 1a. The isolation region 20 is formed by the STI (Shallow Trench Isolation) method or the like.

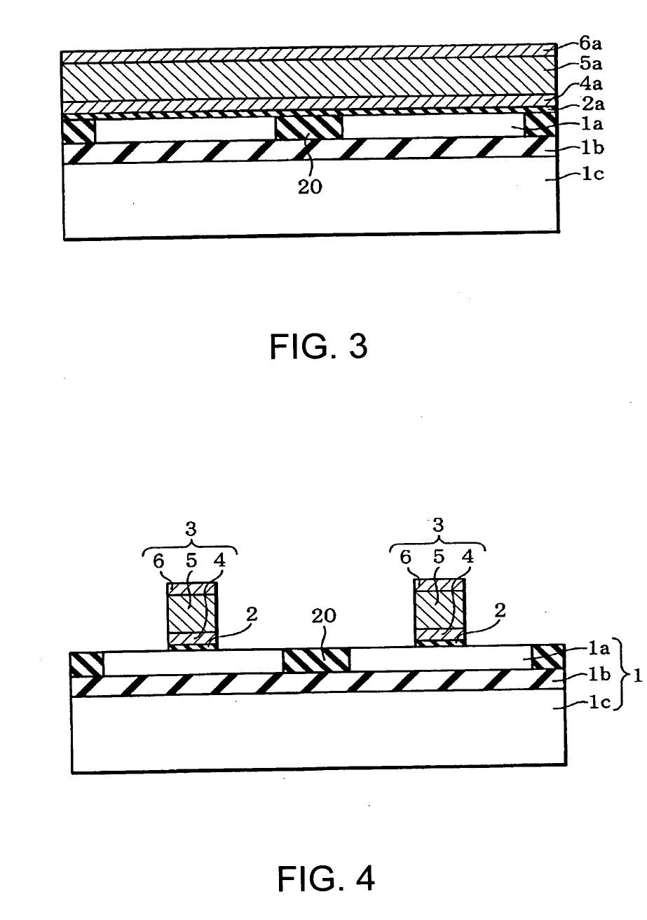

(b) Next, as shown in FIG. 3, an insulating layer 2a that becomes the gate insulating layer is formed by the thermal oxidation method, the CVD method, the direct plasma nitriding method or the like. The thickness of the insulating layer 2a is about 3 nm. As for the insulating layer 2a, a mono-layer of either silicon oxide, silicon nitride and silicon oxynitride, or stacked layers of these can be used.

Next, the first tantalum nitride layer 4a, the tantalum layer 5a of a body-centered cubic lattice phase, and the second tantalum nitride layer 6a as a cap layer are sequentially formed by the sputtering method using a xenon gas.

Taking aspects such as conductivity and threshold characteristic into consideration, as for the first tantalum nitride layer 4a, it is desirable that a composition ratio (x) of nitrogen and tantalum, expressed as TaNₓ, is 0.25 to 1.0.

In the embodiment, a tantalum nitride layer 6 is used as the cap layer. The tantalum nitride has an advantage of being very strong against cleaning chemicals (acid and alkali). The cap layer has a function to prevent oxidization of the tantalum layer 5a in subsequent processes after the etching of the gate electrode. In addition to the tantalum nitride, the cap layer may be formed of at least one type selected from TaSiₓN_{y}, TiNₓ, TiAlₓN_{y}, Si, silicide of a transition metal or the like.

As for the sputtering, by using xenon having a larger mass instead of argon that is usually used, energy can be given only to the surface of the depositing layer, which is in the process of the layer formation, without causing a defect or damage to the gate insulating layer 2a and the semiconductor layer 1a, which are under-layers. That is, against the atomic radius of argon being 0.188 nm, the atomic radius of xenon is as large as 0.217 nm, and does not easily penetrate into layers, thereby giving energy efficiently only on the surface of the layer. In addition, the atomic weight of argon is 39.95, while the atomic weight of xenon is 131.3, and thus the atomic weight of xenon is large compared with argon. For this reason, it can be assumed that the transmission efficiency of energy and momentum of xenon to the layer is low, and thus a defect or damage does not likely to happen easily as compared with argon. Therefore, the tantalum nitride layers 4a and 6a and the tantalum layer 5a can be formed without causing a defect and damage to the gate insulating layer 2a with xenon as compared to argon. This tendency is also true for krypton.

As for the embodiment, with adoption of the layer formation method described above, it is confirmed that the low-resistive tantalum layer 5a of a body-centered cubic lattice phase can be formed by hetero-epitaxy growth by lattice matching to the first tantalum nitride layer 4a. The tantalum of a body-centered cubic lattice phase has a lower resistive as compared with β-tantalum, and is thus suitable for an electrode material. Specifically, as for the tantalum of a body-centered cubic lattice phase, the resistance can be reduced to about one tenth (1/10) of the β-tantalum.

Furthermore, it is preferable that the first tantalum nitride layer 4a, the tantalum layer 5a of a body-centered cubic lattice phase, and the second tantalum nitride layer 6a are formed continuously without being exposed to the atmosphere. If the layer is exposed to the atmosphere during the layer formation, adhesion of moisture and oxide formation on the layer surface occur, which is not desirable.

(c) Next, as shown in FIG. 4, the gate electrode 3 is formed by patterning the first tantalum nitride layer 4a, the tantalum layer 5a, and the second tantalum nitride layer 6a by the lithography technology and the dry etching technology. That is, the gate electrode 3 has a stacked structure of the first tantalum nitride layer 4, the tantalum layer 5 of a body-centered cubic lattice phase, and the tantalum nitride layer 6 as a cap layer. As for the embodiment, the insulating layer 2a also forms the gate insulating layer 2 by being patterned.

The embodiment has a feature that a specific etching gas is used in the dry etching in this patterning. In this step, after forming a resist layer (not shown) having a predetermined pattern by the lithography, two steps of etching are performed in series.

At first, a first etching step of the reactive ion etching is performed using a gas containing NF₃ and fluorocarbon (CF₄ or C₂F₆). As an example of the etching conditions, a ratio of the flow rate (sccm) of NF₃ and CF₄ (CF₄/NF₃) of 70/30, a pressure of 4 mTorr, a substrate temperature of 50° C., and a RF bias of 191 mW/cm² can be employed. The etching rate of the tantalum at this time is about 100 nm/min. In the first etching step, most of the second tantalum nitride layer 6a and the tantalum layer 5a (about 70 to 80% of thickness) are etched. Thus, the time duration required for etching can be reduced by etching the tantalum layer 5a using fluorocarbon, whose etching rate to tantalum is larger as compared to other gases, and NF₃, whose dependency on crystal face orientation is small.

Next, a second etching step of the reactive ion etching is performed using a gas containing SiCl₄, NF₃, and an oxygen-containing material. The “oxygen-containing material” means oxygen or an oxygen compound such as water, and preferably oxygen is used for the embodiment. In the second etching step, the ratio of the flow rate (sccm) of NF₃ to the sum of SiCl₄ and NF₃ (NF₃/(SiCl₄+NF₃) is preferably 1 to 30%, more preferably 5 to 25%. With the ratio of both being within this range, the sidewalls of the conductive layer can be processed perpendicularly or almost perpendicularly in a short time, while making the selection ratio against the insulating layer 2a sufficiently large.

Moreover, as for the etching conditions, it is desirable to include only a small amount of oxygen. Specifically, the concentration (ppm) of oxygen to the sum of SiCl₄ and NF₃ is preferably 10 to 10,000 ppm, more preferably 10 to 4,000 ppm. If the concentration of oxygen is too low, the silicon oxide layer for securing the selection ratio of etching may not be formed reliably, while on the other hand, if the concentration of oxygen is too high, a deposit layer is formed before the conductive layer (in the embodiment, the tantalum layer and the first tantalum nitride layer), which should be etched, is etched completely, and thus etching of the conductive layer may become insufficient. And, if the deposit layer is formed also on the inner wall of the chamber, cleaning of the deposit layer may be required.

As an example of the etching condition, a condition with the flow rate ratio of NF₃ to a mixed gas of SiCl₄ and NF₃ being 10 to 15%, the concentration of oxygen being 10 to 2,000 ppm, the pressure being 9 mTorr, the substrate temperature being 50° C., and the RF bias being 127 mW/cm², can be employed. The etching rate of the tantalum at this time is about 40 nm/min, and the etching rate of the tantalum nitride is about 25 nm/min.

In the second etching step, the tantalum layer 5a and the first tantalum nitride layer 4a can be etched perpendicularly or almost perpendicularly while having a high selection ratio against the insulating layer 2a. The following reasons are assumed for this.

Reaction products of nitrogen, which are mainly derived from NF₃, are deposited on the sidewalls of the conductive layer (the tantalum layer 5a and the first tantalum nitride layer 4a, which are the etched objects). Because the reaction products deposited on the sidewalls of the conductive layer function as a sidewall protection layer of the conductive layer, the sidewalls of the conductive layer can be etched perpendicularly or almost perpendicularly.

Moreover, the following reasons can be considered for the capability of having a high selection ratio against the insulating layer 2a. That is, in the plasma during the etching, FCl is produced by fluorine derived from NF₃, and chlorine derived from SiCl₄. Although FCl can etch the conductive layer (the tantalum layer 5a and the first tantalum nitride layer 4a of the embodiment), the selection ratio against the insulating layer differs depending on the type of an insulating layer. For example, FCl can etch a silicon oxide a little, while FCl can easily etch silicon nitride compared with silicon oxide. Therefore, if an insulating layer is a silicon nitride layer, securing the selection ratio against the insulating layer becomes a problem. However, as for the present invention, by containing a little amount of oxygen in the etching gas, even if a silicon nitride layer is used as the insulating layer, a high selection ratio against the insulating layer can be obtained without etching the insulating layer. That is, with a reaction of silicon derived from SiCl₄ and oxygen, the silicon oxide layer, which is not easily etched by FCl, deposits on the insulating layer 2a. Thus, etching by FCl can be substantially stopped by the deposit layer, formed of the silicon oxide, and as a result, the etching of the silicon nitride layer is not performed. Moreover, even if silicon oxide is used as the insulating layer, the etching by FCl can be substantially stopped by the deposit layer, formed of the silicon oxide, and as a result, the etching of the silicon oxide that exists underneath the deposit layer is not performed.

Thus, according to the present invention, even if a insulating layer, which is to be etched by FCl produced in the plasma, is used, by using a little amount of oxygen in the etching gas, a silicon oxide layer, which is not easily etched by FCl, is formed on the insulating layer, and as a result, the selection ratio of the insulating layer against the conductive layer, which is to be etched, can be increased.

On the other hand, the gate electrode cannot be processed perpendicularly or almost perpendicularly, if an anisotropic etching of the conductive layer is not performed under the above-described conditions. For example, if a fluorine gas such as conventional CF₄ is used as the etching gas, sidewalls of the gate electrode are tapered because having a sufficient selection ratio against the insulating layer is difficult and an isotropic etching is performed. This means that a mask shape for etching is not correctly copied to the etched material. Thus, the gate electrode can not be processed to a desired gate length. Furthermore, if impurities are implanted by the ion-implanting in self-alignment using the tapered gate electrode as the mask, a desired impurity-concentration profile cannot be obtained. Therefore, a considerable negative influence is made in the subsequent step of forming source/drain regions in the semiconductor layer.

Next, the gate insulating layer 2 is formed by patterning the insulating layer 2a by performing the wet etching, as required.

(d) Next, as shown in FIG. 1, with the gate electrode 3 acting as a mask, ion implantation of arsenic ions or phosphorus ions for the NMISFET, and boron ions or difluoride boron ions for the PMISFET are carried out to obtain a concentration of 10²⁰cm⁻³ or more. When forming the impurity layers of the NMISFET and the PMISFET, mask layers (not shown) such as a resist layer are formed on predetermined regions so that the impurity ions of reversed polarity may not be doped. Then, impurity layers 8a and 8b can be formed in self-alignment by carrying out a low-temperature annealing at 700° C. or less, preferably at 450 to 550° C.

Next, after depositing the silicon nitride layer on the whole surface of the SOI substrate 1, where the gate electrode 3 is formed, by the CVD (Chemical Vapor Deposition) method, an etchback is performed by the dry etching method, and a sidewall spacer 9 is formed.

Furthermore, a transition metal layer such as a nickel layer is formed by the sputtering method, and after annealing for silicidation, nickel silicide layers 10a and 10b are formed at exposed regions of the impurities layers 8a and 8b. Such transition metal may include titanium, cobalt or the like that can form silicide. Then, the unreacted transition metal layer on the sidewall 9 is removed by an acid such as sulfuric acid, and the suicide layers 10a and 10b are formed in self-alignment.

Thereafter, by going through a wiring step by the conventional CMOS process technology, an inter-layer insulation layer and a wiring layer are formed, and thus the semiconductor device 1000 can be completed.

The method of manufacturing the semiconductor device includes the following features.

The tantalum layer and the tantalum nitride layer can be etched promptly and in a favorable shape, while securing a high selection ratio against the insulating layer by using the gas containing SiCl₄, NF₃, and the oxygen-containing material (for example, oxygen), when etching the tantalum layer and the silicon nitride layer. Moreover, a total etching time can be reduced by the etching using the gas containing NF₃and fluorocarbon (CF₄ or C₂F₆) prior to the etching using the gas containing SiCl₄, NF₃, and the oxygen-containing material.

Moreover, by having the tantalum nitride layer 4 in contact with the gate insulating layer 2, the following advantage is obtained. The work function of the tantalum nitride is about 4.5 eV, which is extremely close to the intrinsic mid-gap energy 4.61 eV of silicon. As a result, an increase of the absolute value of the flat band voltage in an MOS capacitor is small, and thus there is no need to increase the concentration of the impurities, doped in the channel region for controlling threshold value. Therefore, a decrease of carrier mobility can be prevented and the MISFET with a high current drive capability can be obtained with a high yield.

Furthermore, various experiments conducted to identify the feature of the present invention will be described.
(1) Relationship of a selection ratio of an insulator and a bcc-tantalum

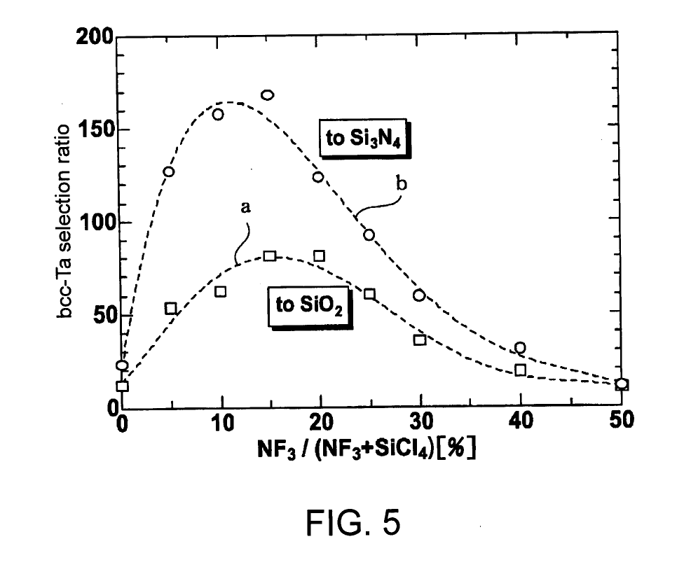

FIG. 5 is a graph showing a relationship between a flow rate ratio of NF₃ to a mixed gas (NF₃+SiCl₄) used in etching, and a selection ratio of an insulator (silicon oxide or silicon nitride) and a bcc-tantalum. In FIG. 5, a graph referred to as a numeral “a” shows the selection ratio of the bcc-tantalum to the silicon oxide, and a graph referred to as a numeral “b” shows the selection ratio of the bcc-tantalum to the silicon nitride.

The conditions of the reactive ion etching include a pressure of 9 mTorr, a substrate temperature of 50° C., and a RF bias of 127 mW/cm². The etching gas includes oxygen with a concentration of 17 ppm. Samples are obtained by forming the silicon oxide layer or the silicon nitride layer having a thickness of about 3 nm on the silicon substrate, and further forming the bcc-tantalum layer having a thickness of 100 nm by sputtering. The silicon oxide layer is formed by thermal oxidation at 750° C. The silicon nitride layer is formed by direct reaction using a high density plasma in an atmosphere of ammonia and an argon gas.

FIG. 5 shows that a sufficiently high selection ratio is obtained when the flow rate ratio of NF₃ to the mixed gas (NF₃+SiCl₄) is 1 to 30%, more preferably 5 to 25%. Taking into consideration a more preferable selection ratio, for example, of 50 or more in the example shown in FIG. 5, 5 to 25% is more preferable in case of the silicon oxide layer. Moreover, in case of the silicon nitride layer, taking into consideration a more preferable selection ratio, for example, of 50 or more in the example shown in FIG. 5, 1 to 30% is preferable, and taking into consideration a more preferable selection ration, for example, of 100 or more in the example shown in FIG. 5, 5 to 25% is preferable.
(2) Relationship of a selection ratio of an insulator and a tantalum nitride.

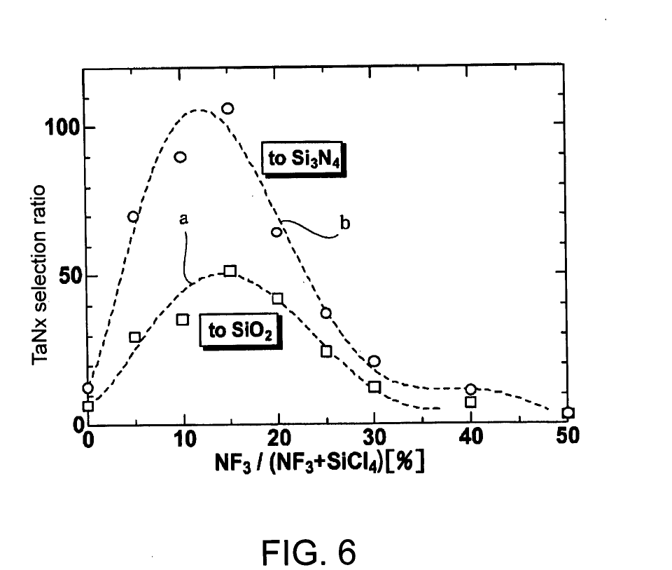

FIG. 6 shows a relationship between a flow rate ratio of NF₃ to a mixed gas (NF₃+SiCl₄) used in the etching, and a selection ratio of an insulator (silicon oxide or silicon nitride) and a tantalum nitride. In FIG. 6, a graph referred to as a numeral “a” shows the selection ratio of the tantalum nitride to the silicon oxide, and a graph referred to as a numeral “b” shows the selection ratio of the tantalum nitride to the silicon nitride.

The conditions of the reactive ion etching are the pressure being 9 mTorr, the substrate temperature being 50° C., and the RF bias being 127 mW/cm². Furthermore, the etching gas includes oxygen with a concentration of 17 ppm. Samples are obtained by forming the silicon oxide layer or the silicon nitride layer having a thickness of 3 nm on the silicon substrate and further forming the tantalum nitride layer having a thickness of 100 nm by the sputtering. The silicon oxide layer is formed by a thermal oxidation at 750° C. The silicon nitride layer is formed by the direct reaction using a high density plasma in an atmosphere of ammonia and an argon gas.

FIG. 6 shows that a sufficiently high selection ratio is obtained when the flow rate ratio of NF₃ to the mixed gas (NF₃+SiCl₄) is 1 to 30%, more preferably 5 to 25%. In particular, taking into consideration a preferable selection ratio, for example, of 20 or more in the example shown in FIG. 6, 5 to 25% is more preferable in case of the silicon oxide layer. Moreover, in case of the silicon nitride layer, taking into consideration a preferable selection ratio, for example, of 20 or more in the example shown in FIG. 6, 1 to 30% is preferable, and taking into consideration a more preferable selection ration, for example, of 50 or more in the example shown of FIG. 6, 5 to 25% is preferable.
(3) Shape observed by SEM

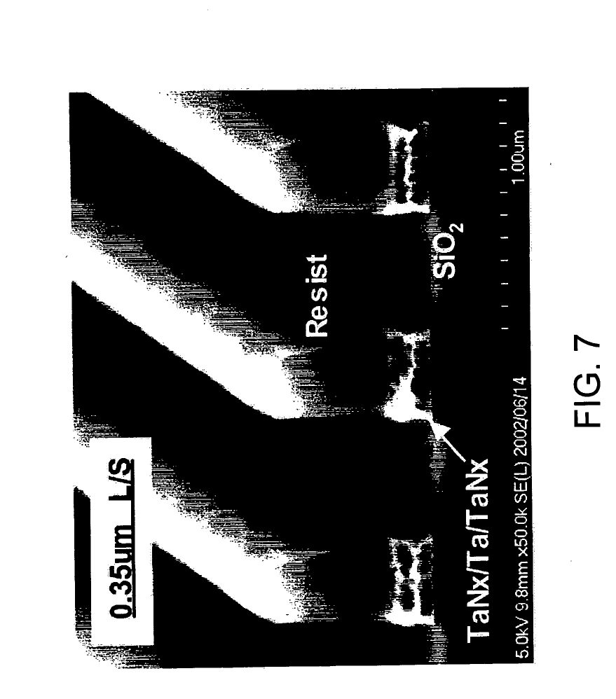

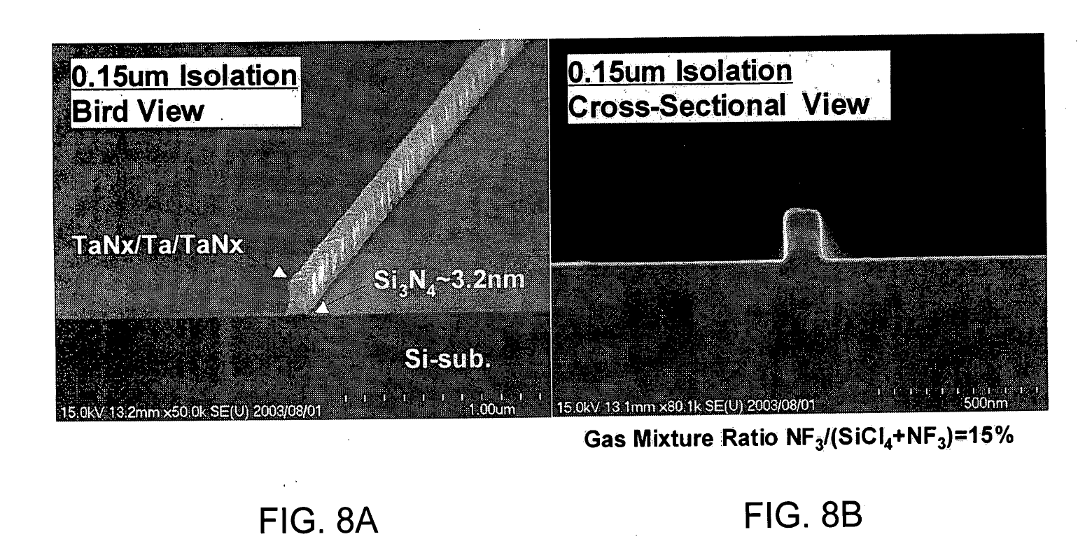

A reactive ion etching is performed with mixed gases of SiCl₄, NF₃ and O₂, using samples formed by the following method. The etching conditions with the flow rate ratio of NF₃ to the mixed gas of SiCl₄ and NF₃ being 15%, the concentration of oxygen being 17 ppm, the pressure being 9 mTorr, the substrate temperature being 50° C., and the RF bias being 127 mW/cm², are employed. The etching rate of the tantalum at this time is about 40 nm/min. Photographs of the samples, obtained in the above process, are taken by a scanning electron microscope (SEM) and are shown in FIG. 7, FIG. 8A, and FIG. 8B. FIG. 7 shows a case that the insulating layer is the silicon oxide layer, FIG. 8A and FIG. 8B show a case that the insulating layer is the silicon nitride layer, while FIG. 8A shows a bird's-eye view, and FIG. 8B shows a cross sectional view.

Samples of this experiment are obtained by the following method.

In case that the insulating layer is the silicon oxide layer, the silicon oxide layer that becomes the gate insulating layer is formed on the silicon substrate by a thermal oxidation method. The thickness of the silicon oxide layer is about 3 nm. Next, the tantalum nitride layer (a thickness of 30 nm), the bcc-tantalum layer (a thickness of 100 nm), and the tantalum nitride layer (a thickness of 30 nm) as a cap layer are sequentially formed by a sputtering method using a xenon gas. A resist layer having a predetermined pattern is formed on a layered structure obtained in this way and provided for the above-mentioned reactive ion etching.

In case that the insulating layer is the silicon nitride layer, the silicon nitride layer that becomes the gate insulating layer is formed on the silicon substrate by high density plasma CVD in an atmosphere of ammonia and an argon gas. The thickness of the silicon nitride layer is about 3 nm. Next, the tantalum nitride layer (a thickness of 30 nm), the bcc-tantalum layer (a thickness of 100 nm), and the tantalum nitride layer (a thickness of 30 nm) as a cap layer are sequentially formed by a sputtering method using a xenon gas. A resist layer having a predetermined pattern is formed on a layered structure obtained in this way and provided for the above-mentioned reactive ion etching.

According to this experiment, it is confirmed from FIG. 7 that the etching is performed such that the layered structure of the tantalum nitride layer/bcc-tantalum layer/tantalum nitride layer has almost perpendicular (89°) sidewalls. Moreover, etching of the silicon oxide layer is not confirmed in this experiment. In addition, in the example shown in FIG. 7, the line/space of the layered structure is 0.35 μm.

According to this experiment, it is confirmed from FIG. 8A and FIG. 8B that the etching is performed such that the layered structure of the tantalum nitride layer/bcc-tantalum layer/tantalum nitride layer has almost perpendicular (89°) sidewalls. In addition, in the example shown in FIG. 8A and FIG. 8B, the line width of the layered structure is 0.15 μm.
(4) Relationship between etching and a deposit material

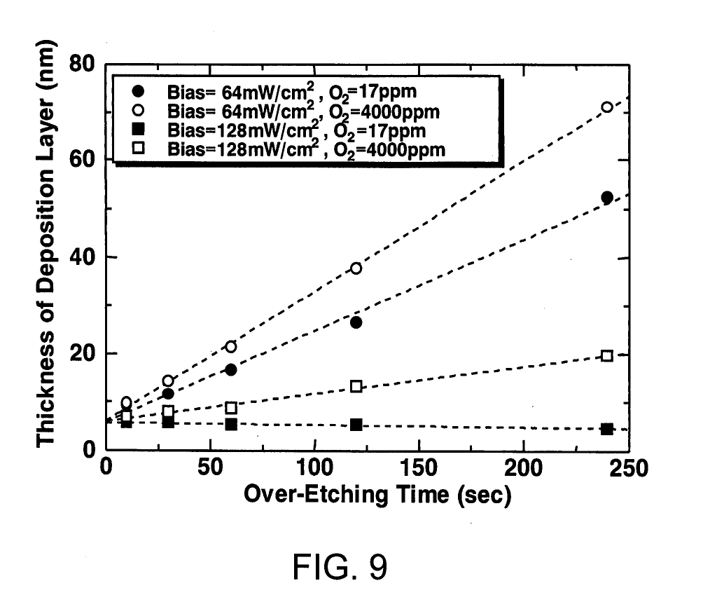

FIG. 9 is a graph showing a relationship of a deposition layer and an over-etching time in etching using mixed gases of SiCl₄, NF₃ and O₂. In FIG. 9, the horizontal axis represents the over-etching time and the vertical axis represents the thickness of the deposition layer. In this experiment, it is confirmed that the deposition layer is dependent on the oxygen concentration and the intensity of RF bias with a following way. At first, the bcc-tantalum layer and the silicon nitride layer of a sample are etched and furthermore over-etched, and then the thickness of a newly formed deposition layer is measured.

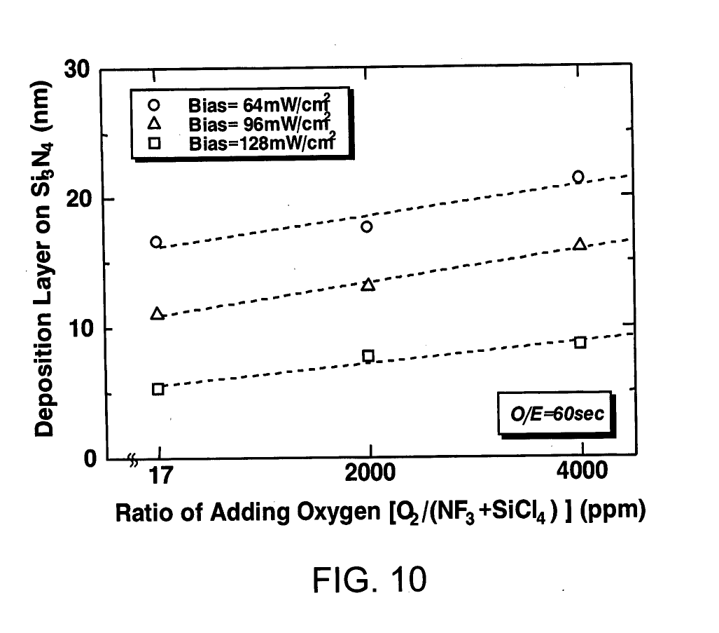

A relationship between the thickness of the deposition layer, the oxygen concentration, and the RF bias intensity obtained from the result of this experiment is shown in FIG. 10. FIG. 10 shows the relationship of the oxygen concentration and the thickness of the deposit layer formed on the silicon nitride layer, when the over-etching time is 60 seconds.

In this experiment, samples, made by forming the silicon nitride layer (a thickness of 3 nm) on the silicon substrate, and further sequentially forming the tantalum nitride layer (a thickness of 30 nm) and the bcc-tantalum layer (a thickness of 100 nm) on the silicon nitride layer, are used. The conditions of the reactive ion etching of the bcc-tantalum layer and the tantalum nitride layer are the pressure being 9 mTorr, the substrate temperature being 50° C., the RF bias being 64 and 128 mW/cm². The flow rate ratio of NF₃ to the mixed gas of SiCl₄ and NF₃ is 15%. The oxygen concentration is 17 ppm, 2,000 ppm, and 4,000 ppm.

It is confirmed from FIG. 9 that upon completion of the etching of the tantalum nitride layer under the etching conditions of this experiment, formation of the deposition layer (in another word, deposition of the reaction products) is started. And it is found that the deposition layer becomes thicker as the over-etching time passes. Furthermore, it is confirmed from FIG. 9 and FIG. 10 that the thickness of the deposit layer is dependent on the intensity of RF bias, wherein the deposition layer becomes thinner as the intensity of RF bias becomes higher, and the deposition layer becomes thicker as the intensity of RF bias becomes lower. Moreover, it is confirmed that the thickness of the deposition layer is dependent on the oxygen concentration, wherein the deposition layer becomes thicker as the oxygen concentration becomes higher. It is assumed that this is because etching of the deposit material, affected by the intensity of RF bias, and the deposition of the deposit material, affected by the oxygen concentration, compete each other.

It is understood that if, for example, the oxygen concentration is low (17 ppm) and the intensity of RF bias is as large as 128 mW/cm², the deposition layer is not formed and the silicon nitride layer is etched a little as time passes. It is assumed that this is because the silicon oxide layer having a sufficient thickness is not formed on the silicon nitride layer due to the low concentration of oxygen. On the other hand, it is confirmed that even if the intensity of RF bias is 128 mW/cm², the deposition layer is formed if oxygen concentration is as high as 2,000 ppm and 4,000 ppm.

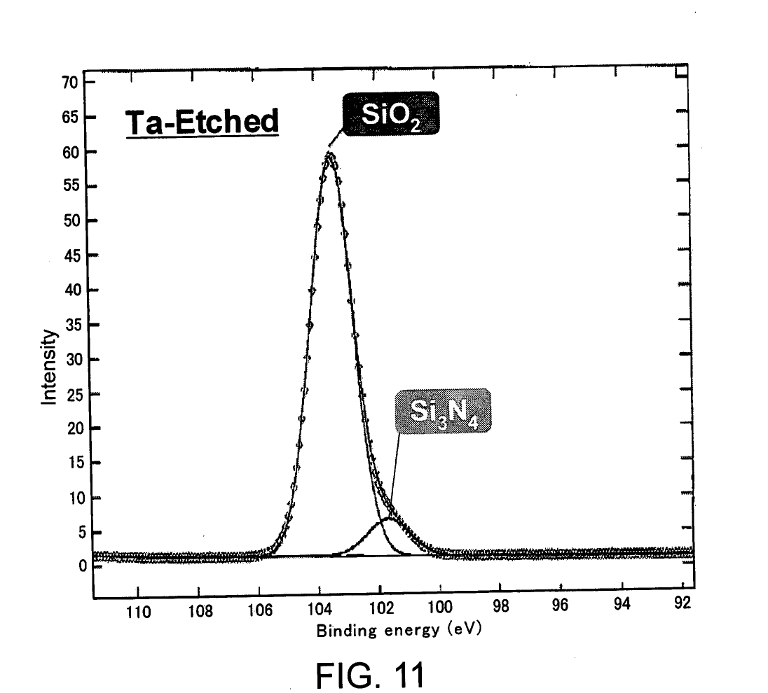

It is confirmed that the deposition layer obtained in this experiment is the silicon oxide by the X-ray Photoelectron Spectral (XPS) analysis. The result of the X-ray electronic spectral analysis is shown in FIG. 11. A peak in FIG. 11 shows that most of the deposition layer, formed on the silicon nitride layer, is made of silicon oxide and silicon nitride exists a little. It is understood that this silicon oxide is formed by a reaction of the silicon, derived from SiCl₄, and the oxygen.

From the result of this experiment, it can be said that in the reactive ion etching, the RF biasing is desirably set while taking into consideration the etching rate and the formation speed of the deposit material.
(5) Vg-Id characteristic of a transistor

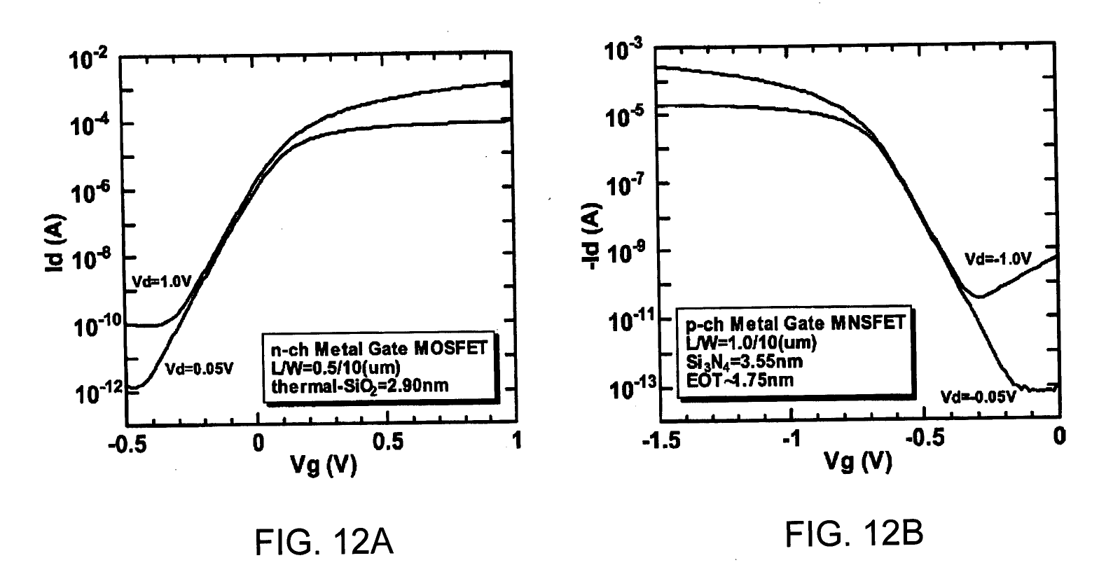

FIG. 12A and FIG. 12B show the Vg-Id characteristic of the transistor concerning this experiment. FIG. 12A shows the Vg-Id characteristic of the n-channel MOSFET, and FIG. 12B shows the Vg-Id characteristic of the p-channel MNSFET. Each of the transistors has a stacked structure of the tantalum nitride layer (a thickness of 30 nm), the bcc-tantalum layer (a thickness of 100 nm), and the tantalum nitride layer (a thickness of 30 nm) as a cap layer. Moreover, the n-channel MOSFET includes the silicon oxide layer (a thickness of 2.9 nm), formed by the thermal oxidation as the gate insulating layer. The p-channel MNSFET includes the silicon nitride layer (a thickness of 3.55 nm), formed by the high density plasma CVD in an ammonia-argon atmosphere as the gate insulating layer. The equivalent oxidization layer thickness (EOT) of the silicon nitride layer is 1.75 nm.

It is confirmed from FIG. 12A and FIG. 12B that each of the p-channel MNSFET and the n-channel MOSFET has an excellent Vg-Id characteristic.
(6) Off-current characteristic of a transistor

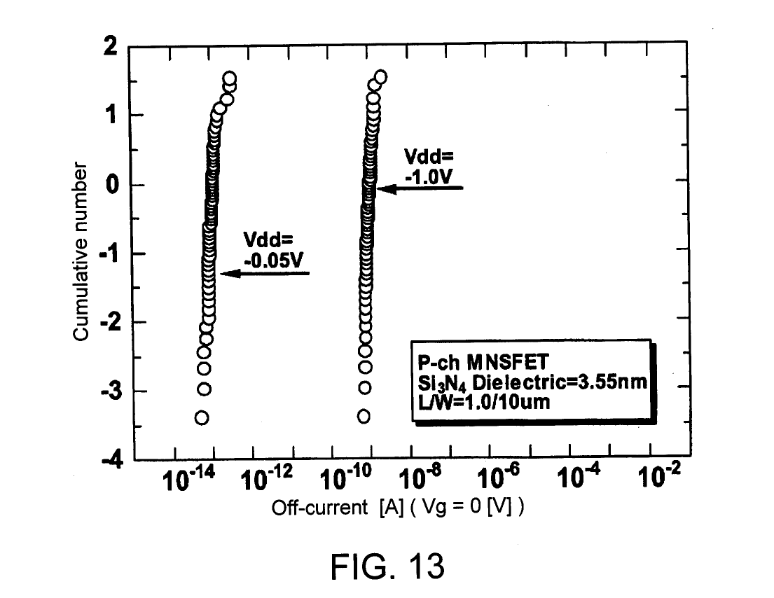

FIG. 13 is a graph showing the off-current characteristic of the same p-channel MNSFET that was used for measurement of the Vg-Id characteristic described above. In FIG. 13, the horizontal axis represents an off-current and the vertical axis represents Weibull cumulative number (Weibull plot obtained by ln(-ln(1-F)). In this experiment, the off-current of the MNSFET of 60 points on a six-inch wafer is measured.

It is confirmed from FIG. 13 that the MNSFET of this experiment has little variation in the off-current and that the gate electrode is etched uniformly with a high selection ratio.

Furthermore, the inventor conducted the following experiment for comparison.

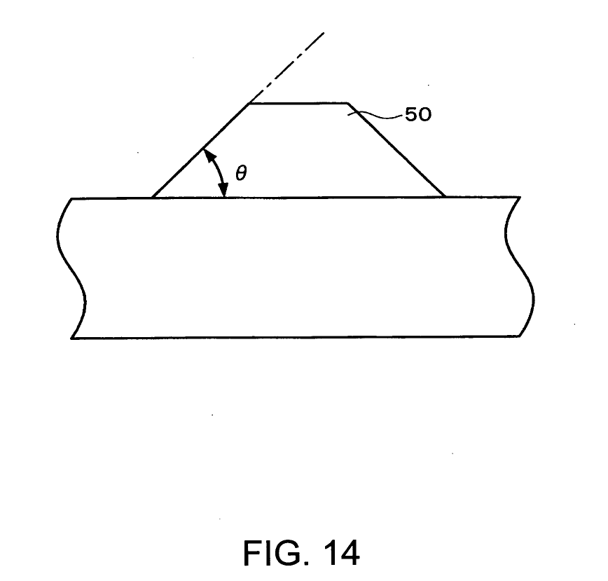

At first, as for the etching of the conductive layer (tantalum), SF₆ is used instead of NF₃. As a result, it is confirmed that the characteristic of isotropic etching by SF₆ is strong compared with that of NF₃. As a result, as shown in FIG. 14, the etched conductive layer (tantalum layer) 50 has a taper shape, and it is confirmed that the taper angle θ is about 60° in this case. Therefore, it is confirmed that in the step of perpendicularly etching the sidewalls of the conductive layer, it is preferable to use NF₃. Moreover, C1₂ is used as the etching gas in stead of SiCl₄. As a result, it is confirmed that deposit material is not deposited sufficiently on the sidewalls of the conductive layer and a practical selection ratio cannot be obtained against the conductive layer and the silicon oxide layer.

As described above, the embodiments suitable for the present invention have been described, however, the present invention can take various types of embodiments within the spirit of the present invention.

For example, the gate electrode is not limited to the stacked structure of the tantalum nitride layer and the tantalum layer. The gate electrode can employ a mono-layer of metal such as tantalum, tungsten, molybdenum, chromium, niobium, vanadium, titanium, zirconium, and hafnium, and a mono-layer of a nitride layer of these metals, or a stacked structure of the metal layer and the nitride layer of the metal.

Furthermore, it is preferable that the conductive layer to be etched is used for the gate electrode, but may be used for another wiring layer.

1. A method of manufacturing a semiconductor device, comprising:
forming an insulating layer above a semiconductor layer;
forming a conductive layer including at least one type selected from the IVa, Va, and VIa group metals and nitrides of these metals above the insulating layer; and
etching the conductive layer using a gas containing SiCl₄, NF₃, and an oxygen-containing material.

2. A method of manufacturing a semiconductor device, comprising:
forming an insulating layer above a semiconductor layer;
forming a conductive layer including at least either a tantalum layer and a tantalum nitride layer above the insulating layer; and
etching the conductive layer using a gas containing SiCl₄, NF₃, and an oxygen-containing material.

3. A method of manufacturing a semiconductor device, comprising in the following order:
forming an insulating layer above a semiconductor layer;
forming a conductive layer including at least either a tantalum layer and a tantalum nitride layer above the insulating layer; and
etching the conductive layer using a gas containing NF₃ and fluorocarbon; and
etching the conductive layer using a gas containing SiCl₄, NF₃, and an oxygen-containing material.

4. The method of manufacturing the semiconductor device according to any of claims 1 through 3, wherein a flow rate ratio of the NF₃ to a sum of the SiCl₄ and the NF₃ is 1 to 30%.

5. The method of manufacturing the semiconductor device according to claim 4, wherein a flow rate ratio of the NF₃ to a sum of the SiCl₄ and the NF₃ is 5 to 25%.

6. The method of manufacturing the semiconductor device according to any of claims 1 through 3, wherein a concentration of the oxygen-containing material to a sum of the SiCl₄ and the NF₃ is 10 to 10,000 ppm.

7. The method of manufacturing the semiconductor device according to any of claims 1 through 3, wherein the oxygen-containing material is oxygen.

8. The method of manufacturing the semiconductor device according to any of claims 1 through 3, wherein the insulating layer includes at least either a silicon oxide layer, a silicon nitride layer, and a silicon oxynitride layer.

9. A method of manufacturing a semiconductor device, comprising:
forming an insulating layer that becomes a gate insulating layer above a semiconductor layer;
forming a first tantalum nitride layer, a tantalum layer of a body-centered cubic lattice phase, and a second tantalum nitride layer above the insulating layer in this order;
forming a gate electrode by etching at least the first tantalum nitride layer and the tantalum layer of a body-centered cubic lattice phase by using a gas containing SiCl₄, NF₃, and an oxygen-containing material; and
forming a first impurity layer and a second impurity layer that form a source region or a drain region by doping impurities into the semiconductor layer.

10. The method of manufacturing the semiconductor device according to claim 9, wherein a flow rate ratio of the NF₃ to a sum of the SiCl₄ and the NF₃ is 1 to 30%.

11. The method of manufacturing the semiconductor device according to claim 10, wherein a flow rate ratio of the NF₃ to a sum of the SiCl₄ and the NF₃ is 5 to 25%.

12. The method of manufacturing the semiconductor device according to any of claims 9 through 11, wherein a concentration of the oxygen-containing material to a sum of the SiCl₄ and the NF₃ is 10 to 10,000 ppm.

13. The method of manufacturing the semiconductor device according to any of claims 9 through 11, wherein the oxygen-containing material is oxygen.

14. The method of manufacturing the semiconductor device according to any of claims 9 through 11, wherein the insulating layer includes at least any of a silicon oxide layer, a silicon nitride layer, and a silicon oxynitride layer.

15. The method of claim 1, wherein the concentration of the oxygen-containing material to a sum of the SiCl₄ and the NF₃ is approximately 10 to approximately 4,000 ppm.

16. The method of claim 9, wherein said first tantalum nitride layer and said second tantalum layer are formed continuously without being exposed to the atmosphere.

17. The method of claim 1, wherein the amount of oxygen-containing material is chosen to have a high selection ratio against the insulating layer.

18. The method of claim 3, wherein the fluorocarbon is selected from the group comprising CF₄ and the C₂F₆.
